(19) United States
(12) Patent Application Publication
(10) Pub. No.: US 2025/0380600 A1
(43) Pub. Date: Dec. 11, 2025

(54) ORGANIC LIGHT-EMITTING APPARATUS

(71) Applicant: CANON KABUSHIKI KAISHA, Tokyo (JP)

(72) Inventor: AKINORI MAKAINO, Kanagawa (JP)

(21) Appl. No.: 19/226,891

(22) Filed: Jun. 3, 2025

(30) Foreign Application Priority Data
Jun. 7, 2024 (JP) 2024-093039

(51) Int. Cl. H10K 59/80; H10K 59/12; H10K 59/124; H10K 59/65

(52) U.S. Cl. CPC H10K 59/878; H10K 59/1201; H10K 59/124; H10K 59/65; H10K 59/80517

(57) ABSTRACT

An organic light-emitting apparatus includes a pixel including a first sub-pixel and a second sub-pixel, each sub-pixels including: a reflective layer and a first electrode. covering the reflective layer. In the first sub-pixel, the drive circuit and the first electrode are electrically connected to each other via a conductive plug. The first electrode of the first sub-pixel is different in thickness from the first electrode of the second sub-pixel.

### BACKGROUND

### Technical Field

The present disclosure relates to an organic light-emitting apparatus, a device using the organic light-emitting apparatus, and an apparatus.

### Description of the Related Art

In recent years, an optical resonator structure has sometimes been used in an organic electroluminescent element (hereinafter, also referred to as “organic EL element” or “organic light-emitting element”). An organic light-emitting element with an optical resonator structure has an anode that is a transparent electrode, and light emitted from the organic light-emitting element passes through the transparent electrode and is reflected by a reflective layer. The light emitted from the organic light-emitting element and the reflected light interfere and reinforce each other, thereby improving the luminous efficiency of the organic light-emitting element. Japanese Patent Application Laid-Open No. 2014-183024 discusses an organic light-emitting element with a configuration that functions as a micro-optical resonator by adjusting the thickness of a transparent electrode.

In the organic light-emitting element discussed in Japanese Patent Application Laid-Open No. 2014-183024, a conductive layer is provided between a lower wire and a reflective electrode layer, and a step height for electrical pixel separation is substantially equal to the sum of the thicknesses of the conductive layer and the transparent electrode layer. During the formation of a partition to surround the reflective electrode layer, the step height causes another step height to be formed in the partition, in a light-emitting layer formed on the partition and the reflective electrode layer, and in a semi-transparent electrode layer formed on the light-emitting layer.

### SUMMARY

This step height may cause abnormal light emission and leakage current due to the local thinning of the light-emitting layer or lead to breakage of the semi-transparent electrode layer.

An aspect of the present disclosure provides an organic light-emitting apparatus with reduced local thinning of the light-emitting layer and reduced breakage of the semi-transparent electrode due to the step height.

According to an aspect of the present disclosure, an organic light-emitting apparatus includes a pixel including a first sub-pixel and a second sub-pixel, a drive circuit disposed on one main surface of a substrate, a first insulating layer covering the drive circuit, reflective layers and first electrodes disposed on the first insulating layer, one of the reflective layers and one of the first electrodes being disposed for the first sub-pixel and another of the reflective layers and another of the first electrodes being disposed for the second sub-pixel, a second insulating layer disposed on the first insulating layer, the second insulating layer separating the first electrode of the first sub-pixel from the first electrode of the second sub-pixel, an organic compound layer disposed on the first electrode and the second insulating layer, the organic compound layer including a light-emitting layer, and a second electrode on the organic compound layer, wherein in the first sub-pixel, the drive circuit and the first electrode are electrically connected to each other via a conductive plug provided in the first insulating layer and including a material different from a material of the first electrode, wherein in the first sub-pixel, the first electrode is in contact with the first insulating layer, the conductive plug, and the reflective layer, and wherein the first electrode of the first sub-pixel is different in thickness from the first electrode of the second sub-pixel.

Further features of the present disclosure will become apparent from the following description of exemplary embodiments with reference to the attached drawings.

### BRIEF DESCRIPTION OF THE DRAWINGS

FIG. 1 is a schematic cross-sectional view illustrating an organic light-emitting apparatus according to a first exemplary embodiment.

FIG. 2 is a schematic plan view illustrating the organic light-emitting apparatus in FIG. 1.

FIGS. 3A to 3E are diagrams illustrating a process of manufacturing the organic light-emitting apparatus in FIG. 1.

FIGS. 4A to 4D are diagrams illustrating a process of manufacturing the organic light-emitting apparatus in FIG. 1.

FIGS. 5A to 5C are diagrams illustrating a process of manufacturing the organic light-emitting apparatus in FIG. 1.

FIG. 6 is a schematic cross-sectional view illustrating an organic light-emitting apparatus according to a second exemplary embodiment.

FIGS. 7A and 7B are diagrams illustrating a method of manufacturing the organic light-emitting apparatus in FIG. 6.

FIG. 8 is a schematic cross-sectional view illustrating an organic light-emitting apparatus according to a third exemplary embodiment.

FIG. 9 is a schematic plan view illustrating the organic light-emitting apparatus in FIG. 8.

FIG. 10 is a schematic view illustrating an example of a display apparatus according to one exemplary embodiment.

FIG. 11A is a schematic view illustrating an example of an imaging apparatus according to one exemplary embodiment, and FIG. 11B is a schematic view illustrating an example of an electronic device according to one exemplary embodiment.

FIG. 12A is a schematic view illustrating an example of a display apparatus according to one exemplary embodiment, and FIG. 12B is a schematic view illustrating an example of a foldable display apparatus.

FIG. 13 is a schematic view illustrating an example of an illumination apparatus according to one exemplary embodiment.

FIGS. 14A and 14B are schematic views illustrating an example of an automobile including a lighting fixture for vehicles according to one exemplary embodiment.

FIG. 15A is a schematic view illustrating an example of a wearable device according to one exemplary embodiment, and FIG. 15B is a schematic view illustrating an example of a wearable device according to one exemplary embodiment, illustrating a configuration that includes an imaging apparatus.

FIG. 16A is a schematic view illustrating an example of an image forming apparatus according to one exemplary embodiment, and FIGS. 16B and 16C are schematic views illustrating an example of an exposure light source of an image forming apparatus according to one exemplary embodiment.

### DESCRIPTION OF THE EMBODIMENTS

Various exemplary embodiments of the present disclosure will be described in detail below with reference to the attached drawings. The exemplary embodiments described below are not intended to limit the disclosure of the claims. While the exemplary embodiments describe a plurality of features, not all of the plurality of features are necessarily essential to the disclosure, and the plurality of features can be combined in any way. Furthermore, in the attached drawings, corresponding or similar structures are assigned to the same reference numerals, and the redundant descriptions are omitted.

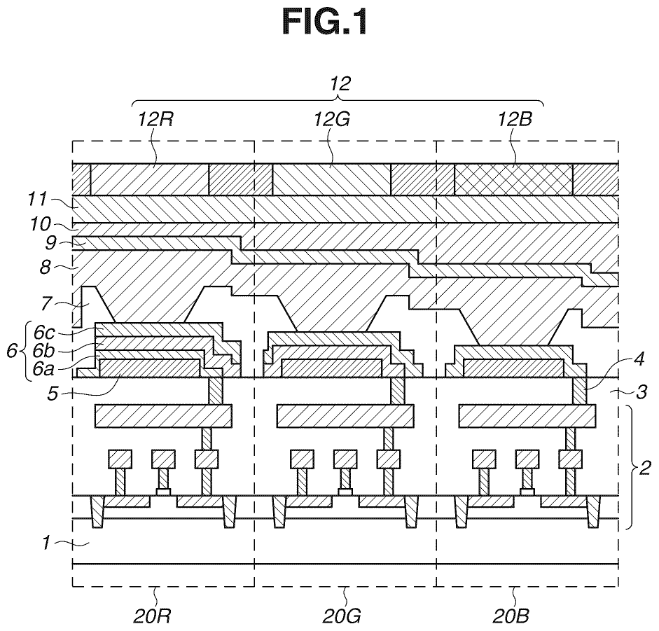

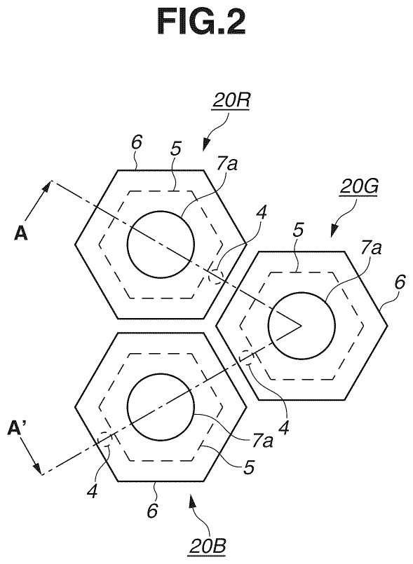

A first exemplary embodiment will be described. An organic light-emitting apparatus according to the first exemplary embodiment will be described with reference to FIGS. 1 and 2. FIG. 1 is a schematic cross-sectional view illustrating the organic light-emitting apparatus according to the first exemplary embodiment in a thickness direction, and FIG. 2 is a schematic plan view illustrating the organic light-emitting apparatus in FIG. 1, specifying positions of reflective layers 5, first electrodes 6, and conductive plugs 4 in a state where up to second insulating layers 7 are formed. FIG. 1 corresponds to a schematic cross-sectional view of an A-A′ portion specified in FIG. 2.

In the organic light-emitting apparatus according to the present exemplary embodiment, each pixel is composed of three sub-pixels 20R, 20G, and 20B, and drive circuits 2 configured to drive the sub-pixels 20R, 20G, and 20B are provided on one main surface of a substrate 1. The drive circuits 2 are covered with a first insulating layer 3. On the first insulating layer 3, the reflective layer 5 and the first electrode 6 are provided for each of the sub-pixels 20R, 20G, and 20B, and an organic compound layer 8 and a second electrode 9 shared by the plurality of sub-pixels 20R, 20G, and 20B are further provided thereon in this order. While the present exemplary embodiment describes a configuration in which each pixel includes three sub-pixels, it is sufficient for each pixel to include two or more sub-pixels.

In each of the sub-pixels 20R, 20G, and 20B, the drive circuit 2 and the first electrode 6 are electrically connected to each other via the conductive plug 4 provided in the first insulating layer 3. Specifically, a wiring layer provided to the drive circuit 2 and the first electrode 6 are connected to each other. The reflective layer 5 and the first electrode 6 are in contact with each other either partially or across the entire surface. Preferably, the first electrode 6 takes the form of covering the entire perimeter of the reflective layer 5 including each side of the reflective layer 5. The first electrode 6 includes a region that is in contact with the first insulating layer 3 between the reflective layer 5 and the conductive plug 4.

In the organic light-emitting apparatus according to the present exemplary embodiment, a moisture barrier layer 10, a planarization layer 11, and a color filter 12 are stacked on the second electrode 9 in this order. Further, the organic light-emitting apparatus according to the present exemplary embodiment may include a microlens (not illustrated).

As the substrate 1, a semiconductor substrate, such as a silicon substrate, or a resin substrate is used.

Materials used in the first insulating layer 3 and the second insulating layer 7 are preferably silicon oxide, silicon oxynitride, or silicon nitride, with silicon oxide being preferred from the viewpoint of ease of processing.

The conductive plug 4 is not particularly limited and may be any conductive plug capable of electrically connecting the drive circuit 2 and the first electrode 6, and specific examples include conductive materials such as tungsten (W). Further, the conductive plug 4 may include a barrier metal such as titanium (Ti), titanium nitride (TiN), or Ti/TiN. Forming the conductive plug 4 from metal provides advantages for miniaturization and electrical stability due to the ease of processing.

The reflective layer 5 is not particularly limited and may be any reflective layer capable of reflecting light but is preferably a reflective layer with a reflectance of 80% or more. Specific examples include high reflectance materials such as aluminum (Al), silver (Ag), and platinum (Pt) and alloys (such as AlCu and AlNi) containing these high reflectance materials.

The first electrode 6 is not particularly limited and may be any electrode capable of transmitting light emitted from the organic compound layer 8 toward the substrate 1 but is preferably a transparent material. Specific examples include indium tin oxide (ITO) or indium zinc oxide (IZO).

In the organic light-emitting apparatus according to the present exemplary embodiment, the drive circuit 2 formed on the substrate 1 transmits an electrical signal to the first electrode 6, and the organic compound layer 8 emits light. A portion of the light emitted from the organic compound layer 8 is reflected by the reflective layer 5. The light emitted from the organic compound layer 8 and the reflected light interfere with and reinforce each other. Therefore, the organic light-emitting apparatus according to the present exemplary embodiment can be considered to have an optical resonator structure. Specifically, the light emitted from the organic compound layer 8 toward the second electrode 9 and the light emitted from the organic compound layer 8 and reflected by the reflective layer 5 interfere with each other in the organic compound layer 8, thereby reinforcing each other.

In the organic light-emitting apparatus according to the present exemplary embodiment, the first electrodes 6 of the sub-pixels 20R, 20G, and 20B in each pixel have different thicknesses from each other. Specifically, the first electrode 6 of the first sub-pixel 20R is composed of electrode layers 6a, 6b, and 6c. The first electrode 6 of the second sub-pixel 20G is composed of the electrode layers 6b and 6c. The first electrode 6 of the third sub-pixel 20B is composed of only the electrode layer 6c. Thus, by adjusting the thickness of the first electrode 6 of each sub-pixel 20, the light emitted from the organic compound layer 8 toward the second electrode 9 and the light emitted from the organic compound layer 8 and reflected by the reflective layer 5 can interfere with each other more efficiently and reinforce each other. The light reinforced through interference, as described above, exits through color filters 12R, 12G, and 12B corresponding to different colors.

In the present specification, a suffix, such as “R”, is added to the end of a reference numeral, such as “12”, to refer to a specific color filter among the plurality of color filters, whereas the term “color filter 12” is used to refer to any of the color filters. The same applies to other components. Similarly, each pixel is composed of a plurality of sub-pixels, and a suffix, such as “R”, is added to the end of a reference numeral, such as “20”, to refer to a specific sub-pixel, whereas the term “sub-pixel 20” is used to refer to any of the sub-pixels.

In FIG. 2, an opening portion 7a of each second insulating layer 7 is an opening portion for electrically connecting the first electrode 6 and the organic compound layer 8 to each other. In the present exemplary embodiment, the first electrode 6 is electrically connected to the reflective layer 5 by covering the reflective layer 5 including each side of the reflective layer 5.

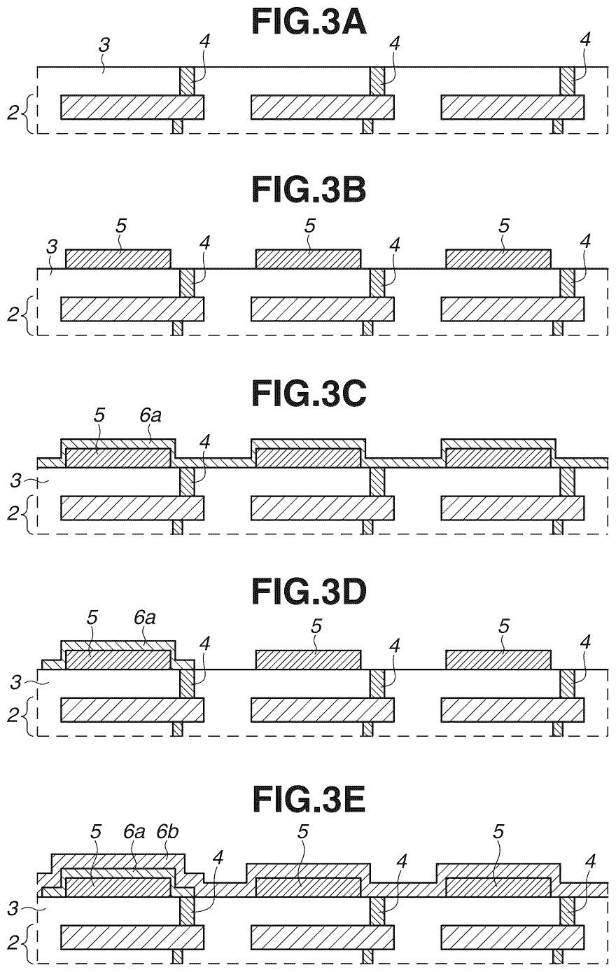

A process for manufacturing the organic light-emitting apparatus according to the present exemplary embodiment will be described with reference to FIGS. 3A to 3E, 4A to 4D, and 5A to 5C. FIGS. 3A to 3E, 4A to 4D, and 5A to 5C are schematic cross-sectional views corresponding to FIG. 1, and for convenience, the illustration of the lower part of the substrate 1 and the drive circuit 2 in FIG. 1 is omitted.

First, as illustrated in FIG. 3A, the drive circuit 2 including a transistor, a capacitor, and a wiring layer is formed on one main surface of a substrate using a publicly-known complementary metal-oxide-semiconductor (CMOS) process. Next, an insulating film is deposited, and the first insulating layer 3 is formed. The first insulating layer 3 may be formed using a plasma chemical vapor deposition (plasma CVD) process, a high-density plasma process, or a combination of these processes. After deposition, the first insulating layer 3 may be planarized using a chemical mechanical polishing (CMP) process. Thereafter, an opening is formed at a predetermined position in the first insulating layer 3. The predetermined position may be on the wiring layer provided to the drive circuit 2. The opening may be formed using a photolithography process or a dry etching process.

In the formed opening, the conductive plug 4 is formed. Excess portions may be removed using a CMP process or an etch-back process.

Next, as illustrated in FIG. 3B, a reflective layer material is deposited on the first insulating layer 3 and patterned into a predetermined shape using a photolithography process, a dry etching process, or a wet etching process, thereby forming the reflective layer 5. The reflective layer material may be deposited using a sputtering process.

In patterning the reflective layer material, the reflective layer material on the conductive plug 4 is removed to expose the conductive plug 4.

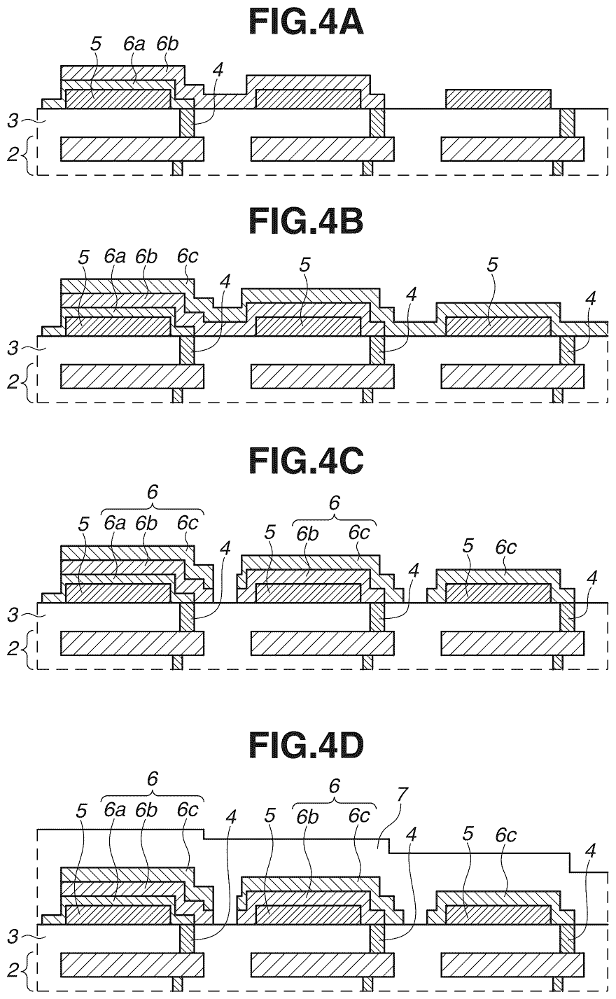

As illustrated in FIGS. 3C to 4B, the deposition and patterning of the electrode layers 6a, 6b, and 6c of the first electrode 6 are then repeated. In the organic light-emitting apparatus according to the present exemplary embodiment, each pixel includes the sub-pixels 20R, 20G, and 20B. The first electrodes 6 of the sub-pixels 20R, 20G, and 20B have different thicknesses from each other, and with such first electrodes 6, an optical resonator structure with optical adjustment layer thicknesses corresponding to the emission colors of the sub-pixels 20 can be formed. In a case where an optical resonator structure can be formed without forming all of the electrode layers 6a to 6c, it is not necessary to form all of the electrode layers 6a to 6c. A configuration in this case will be described below in a third exemplary embodiment. Further, in a case where an optical resonator structure cannot be formed even if all the electrode layers 6a to 6c are formed, another electrode layer may be stacked. Forming the first electrode 6 in contact with the portion where the conductive plug 4 is exposed enables electrical connection between the drive circuit 2 and the first electrode 6 and between the first electrode 6 and the organic compound layer 8 without the reflective layer 5. At this time, the first electrode 6 is also in contact with the first insulating layer 3.

As illustrated in FIG. 4C, the first electrode 6 of each sub-pixel 20 is patterned into a predetermined shape and isolated using a photolithography process, a dry etching process, or a wet etching process. At this time, a step height generated for pixel separation becomes substantially equal to the thickness of the first electrode 6. In this case, the step height for pixel separation is reduced by the thickness of the reflective layer 5 compared to a case where an electrical connection is established between the conductive plug 4 and the reflective layer 5. This makes it possible to reduce the risk of abnormal light emission and leakage current caused by the local thinning of a light-emitting layer on the step height and the risk of breakage of a semi-transparent electrode layer.

In the present exemplary embodiment, the conductive plug 4 and the first electrode 6 are directly connected without the reflective layer 5. By adopting this configuration, the electrical resistance at an interface between the reflective layer 5 and the first electrode 6 is eliminated, compared to a configuration in which the reflective layer 5 is interposed, thereby suppressing a voltage drop between the conductive plug 4 and the first electrode 6.

Further, in a state where a metal interface between the reflective layer 5 and the first electrode 6 is exposed, a defect may occur due to electrical corrosion. Thus, the first electrode 6 is preferably formed to cover the reflective layer 5 including the sides of the reflective layer 5.

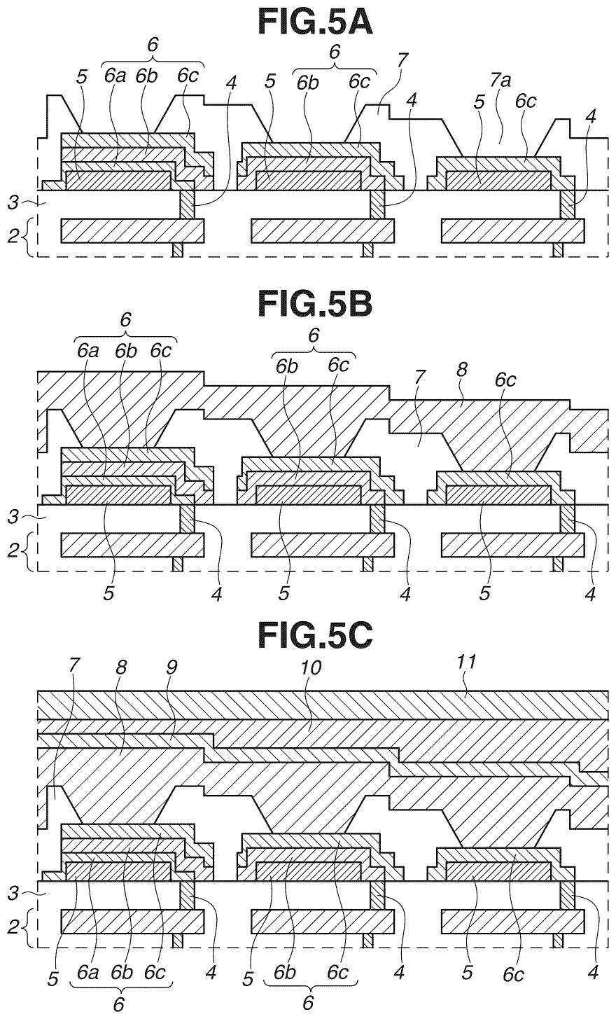

Next, as illustrated in FIGS. 4D and 5A, the second insulating layer 7 is formed on the first electrode 6, and the opening portions 7a are formed at predetermined positions.

Next, as illustrated in FIGS. 5B and 5C, the organic compound layer 8, the second electrode 9, the moisture barrier layer 10, and the planarization layer 11 are formed on the plurality of sub-pixels 20 using a publicly-known process.

Lastly, the color filter 12 is stacked, whereby the organic light-emitting apparatus illustrated in FIG. 1 is obtained.

While the present exemplary embodiment describes an example in which the electrode layer closest to the reflective layer 5 among the electrode layers of the first electrode 6 is connected to the conductive plug 4 in each sub-pixel 20, the organic light-emitting apparatus according to the present exemplary embodiment is not limited to this configuration. For example, the electrode layer 6b or 6c may be connected to the conductive plug 4 in the first sub-pixel 20R, and the electrode layer 6c may be connected to the conductive plug 4 in the second sub-pixel 20G.

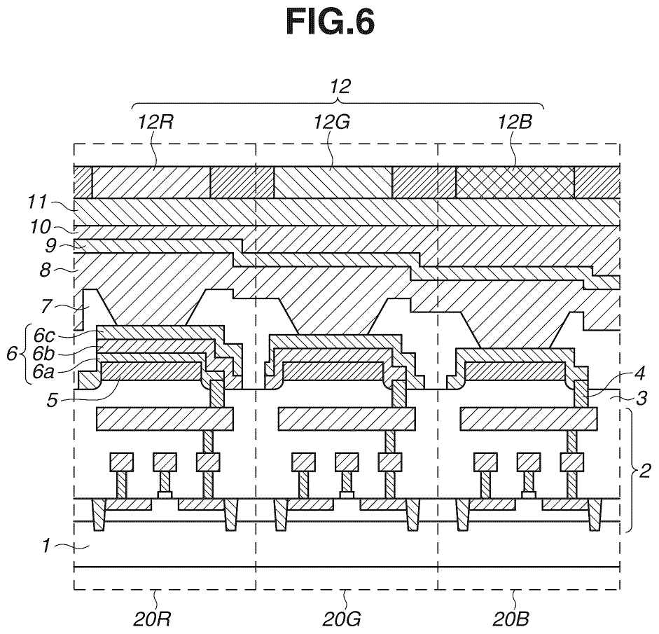

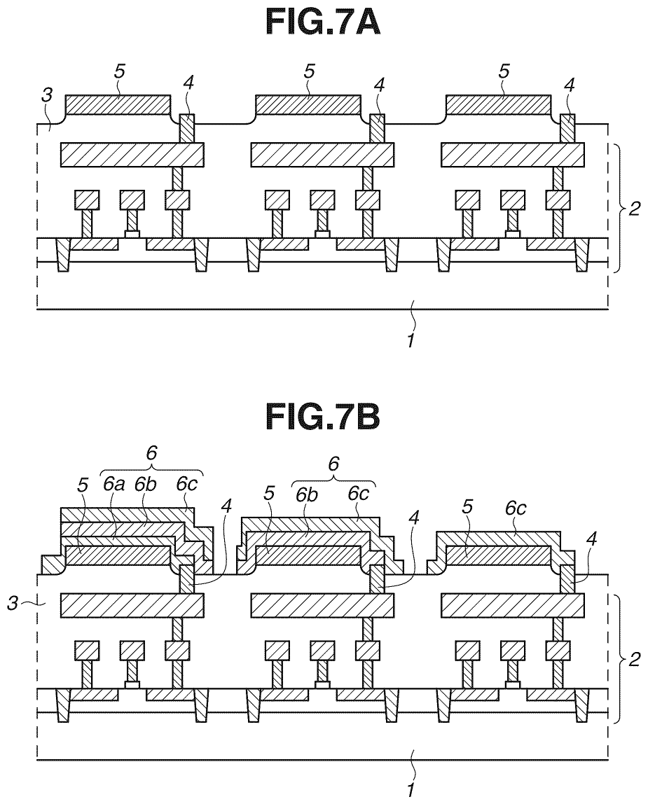

A second exemplary embodiment will be described. FIG. 6 is a schematic cross-sectional view illustrating an organic light-emitting apparatus according to the second exemplary embodiment of the present disclosure in the thickness direction, and FIGS. 7A and 7B illustrate part of a process for manufacturing the organic light-emitting apparatus. In the present exemplary embodiment, the first electrode 6 is also in contact with a side of the conductive plug 4.

In the present exemplary embodiment, a portion of the first insulating layer 3 is removed during patterning of the reflective layer 5 illustrated in FIG. 3B in the first exemplary embodiment to form a shape in which the conductive plug 4 projects from the first insulating layer 3 as illustrated in FIG. 7A. Patterning can be performed using any of a photolithography process, a dry etching process, and a wet etching process. Specifically, the shape in which the conductive plug 4 projects from the first insulating layer 3 can be formed easily by extending the processing time during patterning of the reflective layer 5 by etching.

Thereafter, the first electrode 6 is formed similarly to the processes illustrated in FIGS. 3C to 4C in the first exemplary embodiment, whereby a shape illustrated in FIG. 7B is formed. With the sides of the conductive plug 4 in contact with the first electrode 6 as illustrated in FIG. 7B, the contact area between the conductive plug 4 and the first electrode 6 increases, thereby stabilizing the electrical connection.

Thereafter, the second insulating layer 7 to the planarization layer 11 are formed similarly to the processes illustrated in FIGS. 4D to 5C in the first exemplary embodiment, and then a color filter is formed, whereby the organic light-emitting apparatus illustrated in FIG. 6 is obtained.

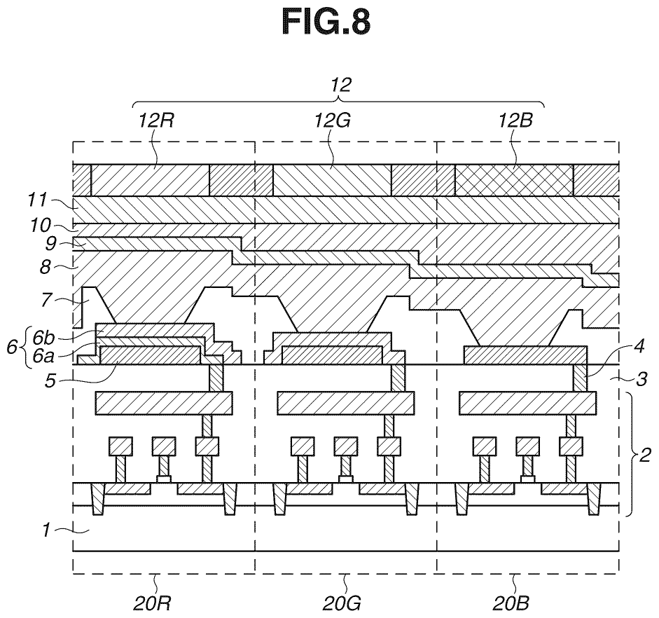

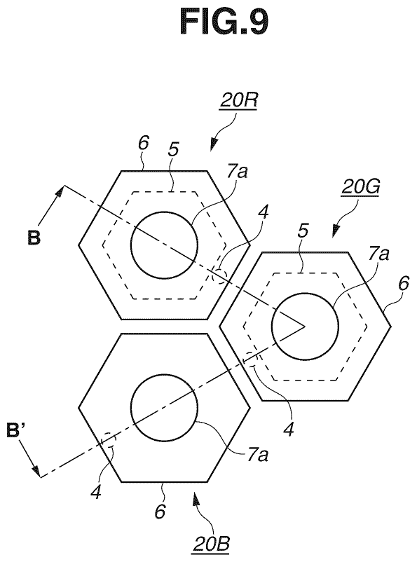

The third exemplary embodiment will be described. An organic light-emitting apparatus according to the third exemplary embodiment will be described with reference to FIGS. 8 and 9. FIG. 8 is a schematic cross-sectional view illustrating the organic light-emitting apparatus according to the present exemplary embodiment in the thickness direction, and FIG. 9 is a schematic plan view illustrating the organic light-emitting apparatus in FIG. 8, specifying the positions of the reflective layers 5, the first electrodes 6, and the conductive plugs 4 in a state where up to the second insulating layers 7 are formed. FIG. 8 corresponds to a schematic cross-sectional view of a B-B′ portion specified in FIG. 9.

In the present exemplary embodiment, no first electrode 6 is formed on the third sub-pixel 20B, and the conductive plug 4 is electrically connected to the reflective layer 5. Further, the reflective layer 5 and the organic compound layer 8 are electrically connected. In the first sub-pixel 20R and the second sub-pixel 20G, the conductive plug 4 is electrically connected to the first electrode 6, and the first electrode 6 is electrically connected to the organic compound layer 8, as in the first and second exemplary embodiments. The configuration in which the reflective layer 5 is electrically connected to the conductive plug 4 may be applied to any sub-pixel and to a plurality of sub-pixels.

A manufacturing process in the present exemplary embodiment is similar to that in the first exemplary embodiment, with the following exceptions. Specifically, the reflective layer 5 is patterned to be in contact with the conductive plug 4 in the third sub-pixel 20B. Further, the first electrode 6 of the first sub-pixel 20R includes the electrode layers 6a and 6b, and the first electrode 6 of the second sub-pixel 20G includes the electrode layer 6b. Furthermore, no first electrode 6 is formed on the third sub-pixel 20B.

Forming an optical resonator structure in the present exemplary embodiment makes it possible to form the organic light-emitting apparatus even in the presence of a sub-pixel 20 that does not require optical path adjustment with the first electrode 6. (Configuration of Organic Light-Emitting Apparatus)

Another configuration of the organic light-emitting apparatus disclosed herein will be described. The organic light-emitting apparatus normally includes an organic light-emitting element including the first electrode 6, the organic compound layer 8, and the second electrode 9 as illustrated in FIG. 1, and the organic compound layer 8 includes at least a light-emitting layer. The organic light-emitting apparatus may further include the substrate 1 and the first insulating layer 3, and the moisture barrier layer 10, the planarization layer 11, and the color filter 12 may be provided on the second electrode 9. Furthermore, a microlens (not illustrated) may be provided. The planarization layer 11 can be made of acrylic resin. Further, a planarization layer may be provided between the color filter 12 and the microlens (not illustrated).

Preferred configurations of the organic light-emitting apparatus disclosed herein and an apparatus that includes the organic light-emitting apparatus will be described.

### Substrate

The substrate 1 may be quartz, glass, a silicon wafer, resin, or metal. Further, the drive circuit 2 including a switching element, such as a transistor, and a wire is provided on the substrate 1, and the first insulating layer 3 is provided thereon, as illustrated in FIG. 1. In the first insulating layer 3, the conductive plug 4 can be formed, and any material can be used as long as insulation from unconnected wires can be ensured. For example, resin such as polyimide, silicon oxide, or silicon nitride can be used.

### Electrode

Among the first electrode 6 and the second electrode 9, the electrode with a higher potential in a case where an electric field is applied in the direction of light emission from the organic light-emitting apparatus becomes an anode, while the other becomes a cathode. Further, the electrode supplying holes to the light-emitting layer can be the anode, and the electrode supplying electrons to the light-emitting layer can be the cathode. In the present disclosure, the first electrode 6 can be either the anode or the cathode.

In the present disclosure, both the first electrode 6 and the second electrode 9 are transparent electrodes, and a transparent conductive oxide layer such as indium tin oxide (ITO) or indium zinc oxide can be used, but this is not a limitation. A photolithography technology can be used for electrode formation.

### Organic Compound Layer

The organic compound layer 8 is composed of, for example, a hole transport layer, a light-emitting layer, and an electron transport layer, and either a multilayer film incorporating a plurality of functional layers, such as a hole injection layer and an electron injection layer for facilitating the supply of holes and electrons to the light-emitting layer, a hole blocking layer and an electron blocking layer for preventing excessive movement of holes and electrons, and a buffer layer for adjusting the movement of holes and electrons from the electrodes, or a single-layer film can be stacked.

The organic compound layer 8 is formed as a common layer on a plurality of sub-pixels and a plurality of pixels. The common layer refers to a layer that is arranged across a plurality of pixels.

For the organic compound layer 8, a dry process such as a vacuum deposition process, an ionized deposition process, sputtering, or plasma can be used. Alternatively, instead of a dry process, a wet process involving dissolution in a suitable solvent and layer formation using a publicly-known coating process (such as spin coating, dipping, casting process, Langmuir-Blodgett (LB) process, or inkjet process) can be used.

In a case where a layer is formed using vacuum deposition or solution coating, crystallization is less likely to occur, resulting in excellent long-term stability. Further, in a case where a coating process is used for deposition, a film can be formed by combining it with a suitable binder resin.

As the binder resin, a polyvinylcarbazole resin, polycarbonate resin, polyester resin, acrylonitrile butadiene styrene (ABS) resin, acrylic resin, polyimide resin, phenol resin, epoxy resin, silicone resin, and urea resin can be used. However, these are not limiting examples.

Furthermore, a single type of binder resin can be used alone as a homopolymer or copolymer, or two or more types of binder resins can be used as a mixture. As necessary, a publicly-known additive, such as a plasticizer, an antioxidant, or an ultraviolet absorber may be used in combination.

### Moisture Barrier Layer

As the moisture barrier layer 10, glass with a desiccant is bonded to the second electrode 9, thereby reducing the infiltration of water into the organic compound layer 8 and the occurrence of a display defect. Further, as another exemplary embodiment, a passivation film such as silicon nitride may be provided on the second electrode 9 to reduce the infiltration of water into the organic compound layer 8. For example, after the second electrode 9 is formed, it may be conveyed into another chamber without breaking the vacuum, and a silicon nitride film with a thickness of 2 um may be formed using a CVD process as the moisture barrier layer 10. The moisture barrier layer 10 may be provided using an atomic layer deposition (ALD) process after the deposition using the CVD process. Materials for the film formed using the ALD process are not limited and may include silicon nitride, silicon oxide, or aluminum oxide. Silicon nitride may be further formed using the CVD process on the film formed using the ALD process. A film formed using the ALD process may be smaller in thickness than that formed using the CVD process. Specifically, it can be 50% or less, or 10% or less.

### Color Filter

The color filter 12 can be formed on the moisture barrier layer 10 or on the planarization layer 11 provided on the moisture barrier layer 10. Further, a color filter that takes into account the size of the organic light-emitting apparatus may be provided on another substrate and bonded to the substrate on which the organic light-emitting apparatus is provided, or the color filter may be high-molecular-weight.

### Planarization Layer

The planarization layer 11 may be provided between the color filter 12 and the moisture barrier layer 10. The planarization layer 11 is provided to reduce the irregularities of the underlying layer. Is it also sometimes referred to as a material resin layer without limiting its purpose. The planarization layer 11 may be made of an organic compound and can be either low-molecular-weight or high-molecular-weight but is preferably high-molecular-weight.

The planarization layers 11 may be provided both above and below the color filter 12, and the constituent materials may be the same as or different from each other. Specifically, a polyvinylcarbazole resin, polycarbonate resin, polyester resin, ABS resin, acrylic resin, polyimide resin, phenol resin, epoxy resin, silicone resin, or urea resin can be used.

### Microlens

The organic light-emitting apparatus may include an optical element, such as a microlens, on its light-emission side. The microlens may be made of acrylic resin or epoxy resin. The microlens may be intended to increase the amount of light extracted from the organic light-emitting apparatus and to control the direction of the extracted light. The microlens may have a hemispherical shape. In a case where it has a hemispherical shape, there is a tangent line that is in contact with the hemisphere and parallel to the insulating layer, and the contact point between this tangent line and the hemisphere is the apex of the microlens. The apex of the microlens can similarly be determined in any cross-sectional view. Specifically, there is a tangent line that is in contact with a semicircle of the microlens and parallel to the insulating layer in a cross-sectional view, and the contact point between this tangent line and the semicircle is the apex of the microlens.

Further, the midpoint of the microlens can also be defined. In a cross-section of the microlens, an imaginary line segment can be drawn from the point where one arc shape ends to the point where another arc shape ends, and the midpoint of this line segment can be defined as the midpoint of the microlens. The cross-section for determining the apex and midpoint may be a cross-section perpendicular to the insulating layer.

### Counter Substrate

A counter substrate may be provided on the color filter 12 or on the planarization layer 11 on the color filter 12. The counter substrate is provided at a position corresponding to the substrate 1 and is thus referred to as the counter substrate. The material of the counter substrate may be the same as that of the substrate 1.

### Drive Circuit

The organic light-emitting apparatus includes the drive circuit 2. The drive circuit 2 may be a drive circuit for an active matrix display apparatus that independently controls the light emission of a plurality of organic light-emitting elements. The active matrix circuit may use either voltage programming or current programming. The drive circuit 2 includes a transistor for driving the organic light-emitting element and is provided for each pixel. Specifically, the drive circuit 2 includes a transistor that controls the luminance of the light-emitting element. Further, the drive circuit 2 may include one or more of a transistor that controls the timing of light emission, a capacitor that holds a gate voltage of the transistor that controls the luminance, and a transistor for connecting to ground (GND) without passing through the light-emitting element.

The organic light-emitting apparatus includes a display region and a peripheral region around the display region. The display region includes a pixel circuit, and the peripheral region includes a display control circuit. The mobility of a transistor included in the pixel circuit may be smaller than that of a transistor included in the display control circuit. A gradient of the current-voltage characteristic of the transistor included in the pixel circuit may be smaller than that of the current-voltage characteristic of the transistor included in the display control circuit. The gradient of the current-voltage characteristic can be measured by the so-called Vg-Ig characteristic. The transistor included in the pixel circuit is a transistor connected to the organic light-emitting element.

### Pixel

The organic light-emitting apparatus may include a plurality of pixels. Each pixel includes the sub-pixels 20 configured to emit different colors from each other. For example, the sub-pixels 20 may each have an RGB emission color.

Each pixel emits light in a region also referred to as a pixel aperture. The pixel aperture may be 15 μm or less, or 5 μm or more. More specifically, it may be 11 μm, 9.5 μm, 7.4 μm, or 6.4 μm. The space between sub-pixels may be 10 μm or less, or more specifically, 8 μm, 7.4 μm, or 6.4 μm.

The pixels may be arranged in a publicly-known form in a plan view. Examples of the pixels include stripe, delta, pentile, and Bayer arrangements. The shape of the sub-pixel 20 in a plan view can be any publicly-known shape. Examples of the shape include a rectangle, a quadrilateral such as a rhombus, and a hexagon. If the shape is not exact but resembles a rectangle, it may be considered as a rectangle. The sub-pixel shape and the pixel arrangement can be used in combination.

### Applications of Organic Light-Emitting Apparatus

The organic light-emitting apparatus disclosed herein can be used as a component of a display apparatus or an illumination apparatus.

Other applications include an exposure light source for an electrophotographic image forming apparatus, a backlight for a liquid crystal display apparatus, and a light-emitting apparatus including a white light source and a color filter.

The display apparatus may be an image information processing apparatus that includes an image input unit for inputting image information from an area charge-coupled device (area CCD), a linear charge-coupled device (linear CCD), or a memory card, includes an information processing unit configured to process the input information, and displays the input image on a display unit. The display apparatus may include a plurality of pixels, and at least one of the plurality of pixels may include the organic light-emitting apparatus disclosed herein and a transistor connected to the organic light-emitting apparatus.

Further, a display unit of an imaging apparatus or an inkjet printer may have a touch panel function. The driving method for this touch panel function can be any of the infrared, capacitive, resistive, or electromagnetic induction methods, and is not particularly limited. Further, the display apparatus may be used in a display unit of a multi-function printer.

Next, a display apparatus according to the present exemplary embodiment will be described with reference to the drawings.

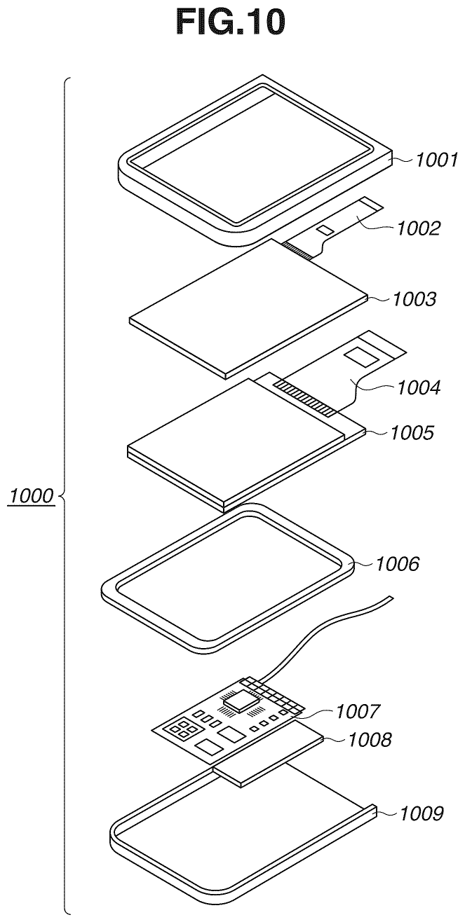

FIG. 10 is a schematic view illustrating an example of the display apparatus according to the present exemplary embodiment. A display apparatus 1000 includes a touch panel 1003, a display panel 1005, a frame 1006, a circuit board 1007, and a battery 1008 between an upper cover 1001 and a lower cover 1009. A flexible printed circuit FPC 1002 is connected to the touch panel 1003, and a flexible printed circuit FPC 1004 is connected to the display panel 1005. A transistor is printed on the circuit board 1007. In a case where the display apparatus is not a mobile device, the battery 1008 may be omitted, and even in a case where the display apparatus is a mobile device, the battery 1008 may be provided at a different position.

The display apparatus according to the present exemplary embodiment may include a color filter with red, green, and blue. In the color filter, the red, green, and blue may be arranged in a delta pattern.

The display apparatus according to the present exemplary embodiment is used in a display unit of a mobile terminal. In this case, it may have both a display function and an operational function. Examples of mobile terminals include mobile phones such as smartphones, tablets, and head-mounted displays.

The display apparatus according to the present exemplary embodiment is used in a display unit of an imaging apparatus including an optical unit with a plurality of lenses and an image sensor configured to receive light passing through the optical unit. The imaging apparatus may include a display unit configured to display information acquired by the image sensor. Further, the display unit may be externally exposed from the imaging apparatus or arranged within a finder. The imaging apparatus may be a digital camera or a digital video camera.

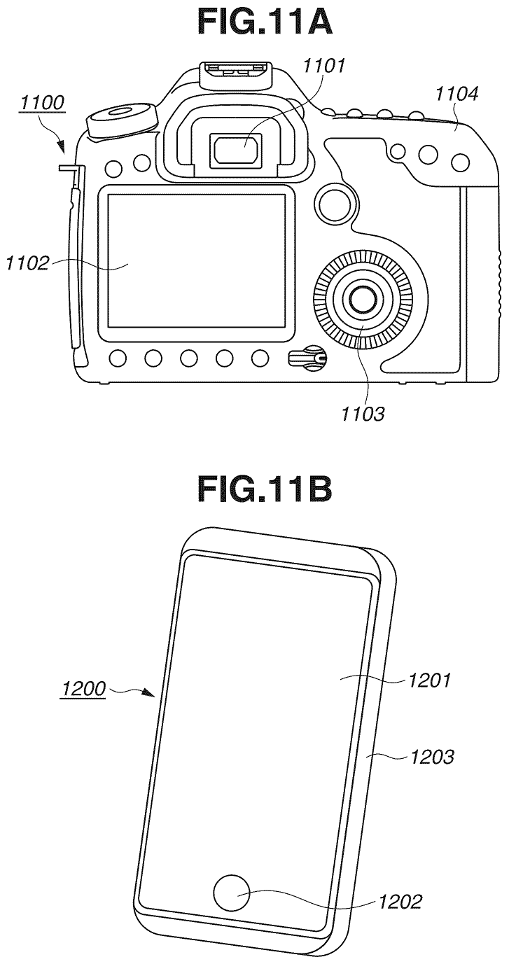

FIG. 11A is a schematic view illustrating an example of an imaging apparatus according to the present exemplary embodiment. An imaging apparatus 1100 includes a viewfinder 1101, a rear display 1102, an operation unit 1103, and a housing 1104. The viewfinder 1101 includes the display apparatus according to the present exemplary embodiment. In this case, the display apparatus may display not only a captured image but also environmental information and an imaging instruction. The environmental information may include the intensity and orientation of external light, the speed at which a subject is moving, and the possibility of the subject being blocked by an obstruction.

The optimal timing for imaging is brief, and it is preferable to display the information as quickly as possible. The response speed of the organic light-emitting apparatus is fast, and thus the display apparatus using the organic light-emitting apparatus disclosed herein is preferably used. The display apparatus using the organic light-emitting apparatus is more suitable than the apparatuses and liquid crystal display apparatuses required to have a high display speed.

The imaging apparatus 1100 includes an optical unit (not illustrated). The optical unit includes a plurality of lenses and forms an image on an image sensor placed within the housing 1104. By adjusting the relative positions of the plurality of lenses, the focus can be adjusted. This operation can be performed automatically. The imaging apparatus may also be referred to as a photoelectric conversion apparatus. The photoelectric conversion apparatus may include, as imaging methods, a method of detecting a difference from a previous image and a method of extracting from an image that is continuously recorded, instead of using sequential imaging.

FIG. 11B is a schematic view illustrating an example of an electronic device according to the present exemplary embodiment. An electronic device 1200 includes a display unit 1201, an operation unit 1202, and a housing 1203. The housing 1203 may include a circuit, a printed circuit board including the circuit, a battery, and a communication unit. The operation unit 1202 may be a button or a reactive unit using a touch panel method. The operation unit 1202 may be a biometric recognition unit recognizes a fingerprint and unlocks a lock. The electronic device including the communication unit can also be referred to as a communication device. The electronic device may also have a camera function by including a lens and an image sensor. An image captured by the camera function is displayed on the display unit 1201. Examples of electronic devices include smartphones and laptop computers.

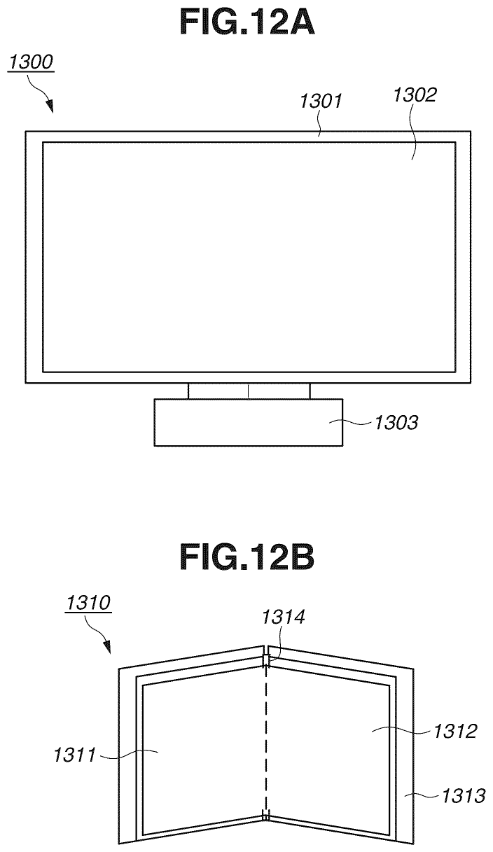

FIGS. 12A and 12B are schematic views illustrating examples of the display apparatus according to the present exemplary embodiment. FIG. 12A illustrates a display apparatus such as a television monitor or a personal computer (PC) monitor. A display apparatus 1300 includes a frame 1301 and a display unit 1302. The organic light-emitting apparatus disclosed herein is used in the display unit 1302. A base 1303 supporting the frame 1301 and the display unit 1302 is also included. The base 1303 is not limited to the form illustrated in FIG. 12A. The lower side of the frame 1301 may also serve as a base. Further, the frame 1301 and the display unit 1302 may be curved. The radius of curvature may fall within the range of 5000 mm to 6000 mm.

FIG. 12B is a schematic view illustrating another example of the display apparatus according to the present exemplary embodiment. A display apparatus 1310 in FIG. 12B is configured to be foldable and is a so-called foldable display apparatus. The display apparatus 1310 includes a first display unit 1311, a second display unit 1312, a housing 1313, and a bending point 1314. The first display unit 1311 and the second display unit 1312 include the organic light-emitting apparatus disclosed herein. The first display unit 1311 and the second display unit 1312 may be a single seamless display apparatus. The first display unit 1311 and the second display unit 1312 can be separated at the bending point 1314. The first display unit 1311 and the second display unit 1312 may each display a different image, or the first display unit 1311 and the second display unit 1312 may together display a single image.

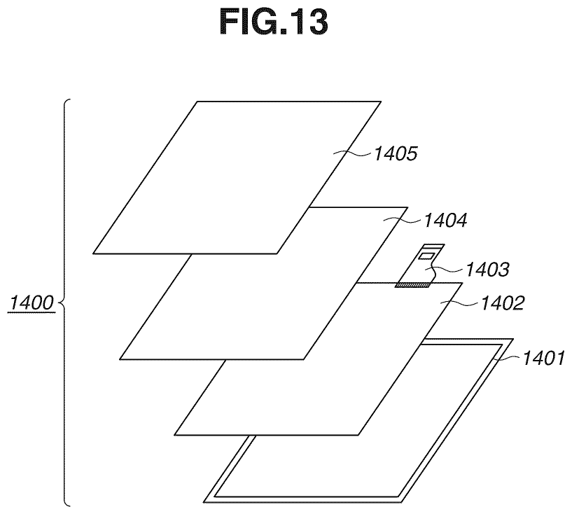

FIG. 13 is a schematic view illustrating an example of an illumination apparatus according to the present exemplary embodiment. An illumination apparatus 1400 includes a housing 1401, a light source 1402, a circuit board 1403, an optical filter 1404, and a light diffusion unit 1405. The light source 1402 includes the organic light-emitting apparatus disclosed herein. The optical filter 1404 may be a filter for improving the color rendering of the light source 1402. The light diffusion unit 1405 can effectively diffuse the light from the light source 1402, such as in lighting, and deliver light over a wide area. The optical filter 1404 and the light diffusion unit 1405 may be provided on the light-emission side of the illumination. As necessary, a cover may be provided at the outermost portion.

The illumination apparatus 1400 is, for example, an apparatus for illuminating a room. The illumination apparatus 1400 may emit white, daylight white, or any color ranging from blue to red. A dimming circuit for adjusting their brightness may also be included. The illumination apparatus 1400 includes the organic light-emitting apparatus disclosed herein and a power circuit connected to the organic light-emitting apparatus. The power circuit is a circuit that converts alternating current voltage to direct current voltage. Further, the white refers to a color temperature of 4200 Kelvin (K), and the daylight white refers to a color temperature of 5000 K. The illumination apparatus 1400 may include a color filter.

Further, the illumination apparatus 1400 according to the present exemplary embodiment may include a heat dissipation unit. The heat dissipation unit releases heat from the inside of the apparatus to the outside of the apparatus, and examples include metals with high specific heat and liquid silicone.

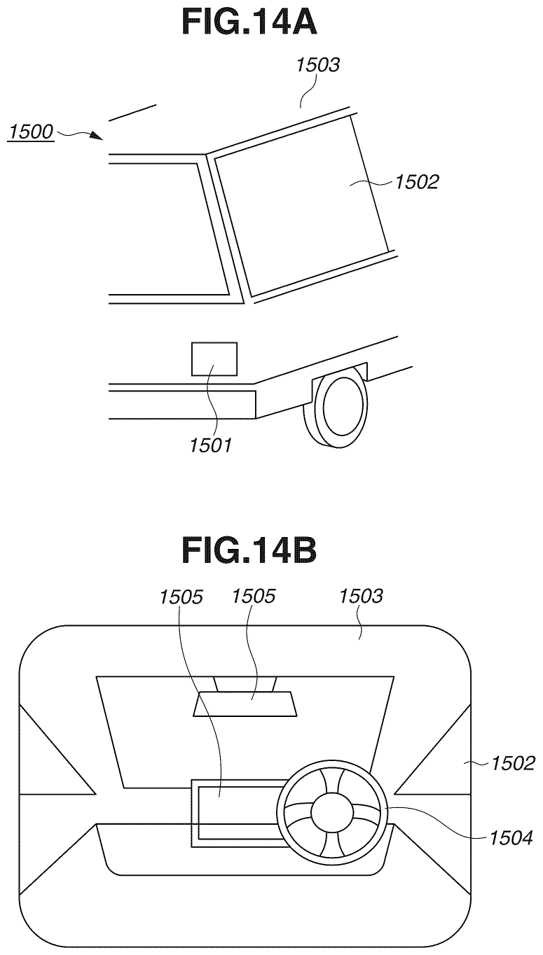

FIGS. 14A and 14B are schematic views illustrating an automobile as an example of a movable unit according to the present exemplary embodiment. As illustrated in FIG. 14A, the automobile includes a tail light, which is an example of a lighting fixture. An automobile 1500 includes a tail light 1501 and may be configured to light the tail light 1501 when a brake operation is performed.

The tail light 1501 includes the organic light-emitting apparatus disclosed herein. The tail light 1501 may include a protection member to protect the organic light-emitting apparatus. The protection member may be made of any material with a certain level of high strength and transparency but is preferably made of polycarbonate. A flange carboxylic acid derivative or an acrylonitrile derivative may be mixed with polycarbonate.

The automobile 1500 may include a body 1503 and a window 1502 fitted to it. The window 1502 may be a transparent display if the window 1502 is not a window for checking the front or rear of the automobile 1500. The transparent display includes the organic light-emitting apparatus disclosed herein. In this case, components such as the electrodes of the organic light-emitting apparatus are transparent.

Further, as illustrated in FIG. 14B, the automobile 1500 includes a steering wheel 1504 and a display unit 1505 mounted on the body 1503. The steering wheel 1504 is used to control the direction in which the movable unit moves. The display unit 1505 displays a map, a location of the movable unit, and a direction in which the movable unit turns. The display unit 1505 includes the organic light-emitting apparatus disclosed herein.

While an example in which the movable unit is an automobile is described, the movable unit according to the present exemplary embodiment may be a ship, an aircraft, or a drone. The movable unit includes a body, a lighting fixture, and a display unit, and the lighting fixture and the display unit are provided to the body. The lighting fixture emits light to indicate the location of the body. One of the lighting fixture and the display unit includes the organic light-emitting apparatus disclosed herein.

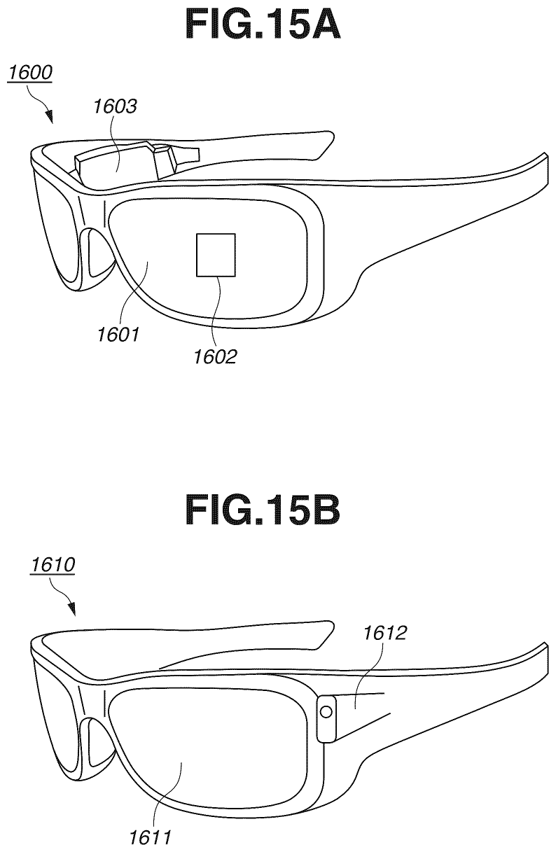

An example of an application of the display apparatus according to the exemplary embodiment will be described with reference to FIGS. 15A and 15B. The display apparatus is applicable to a system that is wearable as a wearable device, such as smart glasses, a head-mounted display (HMD), or smart contact lenses. An imaging display apparatus used in such an example of an application includes an imaging apparatus capable of photoelectrically converting visible light and a display apparatus capable of emitting visible light.

FIG. 15A illustrates eyeglasses 1600 (smart glasses) in one example of an application. An imaging apparatus 1602, such as a CMOS sensor or a single photon avalanche diode (SPAD), is provided on the front of a lens 1601 of the eyeglasses 1600. Further, the display apparatus according to the exemplary embodiment is provided on the back of the lens 1601.

The eyeglasses 1600 further include a control apparatus 1603. The control apparatus 1603 functions as a power supply that supplies power to the imaging apparatus 1602 and the display apparatus according to the exemplary embodiment. Further, the control apparatus 1603 controls the operation of the imaging apparatus 1602 and the display apparatus. An optical system for focusing light on the imaging apparatus 1602 is formed on the lens 1601.

FIG. 15B illustrates eyeglasses 1610 (smart glasses) in one example of an application. The eyeglasses 1610 include a control apparatus 1612, and an imaging apparatus corresponding to the imaging apparatus 1602 illustrated in FIG. 15A and a display apparatus are installed in the control apparatus 1612. An optical system for projecting light from the imaging apparatus and the display apparatus installed in the control apparatus 1612 is formed on a lens 1611, and an image is projected onto the lens 1611. The control apparatus 1612 functions as a power supply that supplies power to the imaging apparatus and the display apparatus, and also controls the operation of the imaging apparatus and the display apparatus. The control apparatus 1612 may include a line-of-sight detection unit configured to detect the line of sight of the wearer. Infrared light may be used to detect the line of sight. An infrared light-emitting unit emits infrared light toward the eyeball of the user gazing at the displayed image. An imaging unit including a light-receiving element detects the emitted infrared light reflected from the eyeball, thereby capturing an image of the eyeball. A reduction unit for reducing light from the infrared light-emitting unit to the display unit in the planar view is included to reduce the degradation of image quality.

The line of sight of the user toward the displayed image is detected from the captured image of the eyeball obtained through infrared imaging. Any publicly-known method is applicable to the line-of-sight detection using the captured image of the eyeball. For example, a line-of-sight detection method based on Purkinje images formed by emitted light reflected from the cornea can be used. More specifically, line-of-sight detection based on a pupil center corneal reflection method is performed. By calculating a line-of-sight vector representing the orientation (rotation angle) of the eyeball using the pupil center corneal reflection method based on the pupil and Purkinje images included in the captured image of the eyeball, the line of sight of the user is detected.

The display apparatus according to the present exemplary embodiment may include an imaging apparatus including a light-receiving element and control the displayed image on the display apparatus based on information about the line of sight of the user from the imaging apparatus. Specifically, the display apparatus determines a first field-of-view region where the user gazes and a second field-of-view region other than the first field-of-view region based on the information about the line of sight. The first field-of-view region and the second field-of-view region may be determined by a control apparatus of the display apparatus, or the first field-of-view region and the second field-of-view region that are determined by an external control apparatus may be received. In a display region of the display apparatus, the display resolution of the first field-of-view region may be controlled to be higher than that of the second field-of-view region. In other words, the resolution of the second field-of-view region may be set lower than that of the first field-of-view region.

Further, the display region includes a first display region and a second display region different from the first display region, and a region with high priority is determined from the first display region and the second display region based on the information about the line of sight. The first field-of-view region and the second field-of-view region may be determined by the control apparatus of the display apparatus, or the first field-of-view region and the second field-of-view region that are determined by an external control apparatus may be received. The resolution of the region with high priority may be controlled to be higher than that of the region other than the region with high priority. In other words, the resolution of the region with relatively low priority may be set low.

Artificial intelligence (AI) may be used to determine the first field-of-view region or the region with high priority. AI may be a model configured to estimate the angle of the light of sight and the distance to the object at the end of the line of sight from the image of the eyeball using the image of the eyeball and the actual gaze direction of the eyeball of the image as training data. An AI program may be stored in the display apparatus, the imaging apparatus, or an external apparatus. In a case where the AI program is stored in the external apparatus, the AI program is transmitted to the display apparatus via communication.

In a case where display control is performed based on gaze detection, it can be effectively applied to smart glasses that also include an imaging apparatus to capture the external environment. The smart glasses can display captured external information in real time.

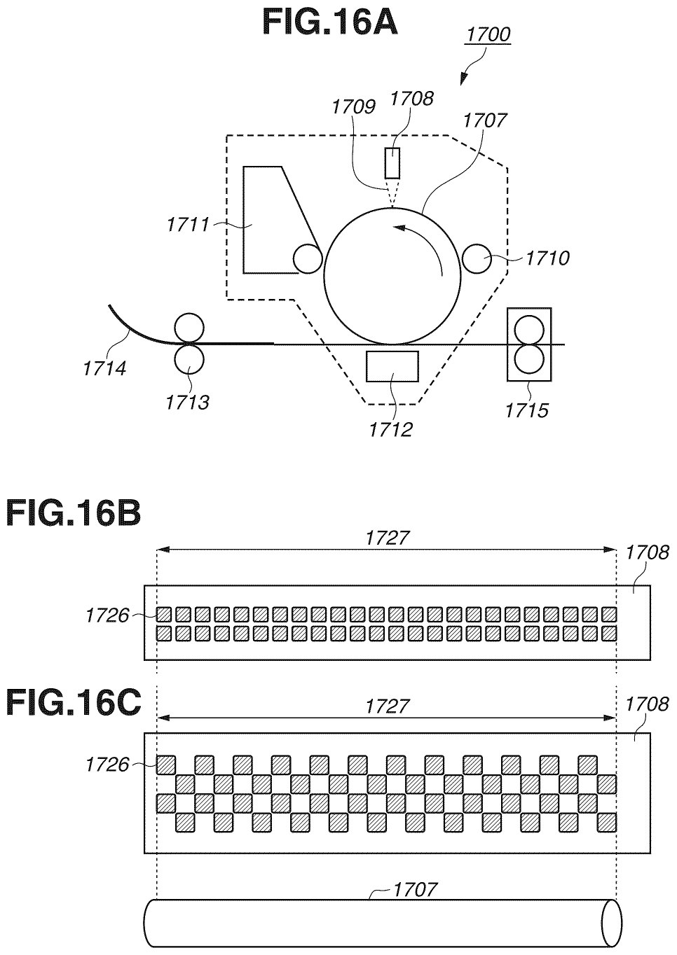

FIG. 16A is a schematic view illustrating an example of an image forming apparatus according to one exemplary embodiment of the present disclosure.

An image forming apparatus 1700 is an electrophotographic image forming apparatus and includes a photosensitive member 1707, an exposure light source 1708, a charging unit 1710, a developing unit 1711, a transfer device 1712, conveying rollers 1713, and a fixing device 1715. Light 1709 is emitted from the exposure light source 1708, and an electrostatic latent image is formed on a surface of the photosensitive member 1707. The exposure light source 1708 includes the organic light-emitting apparatus disclosed herein. The developing unit 1711 contains toner. The charging unit 1710 charges the photosensitive member 1707. The transfer device 1712 transfers the developed image to a recording medium 1714. The conveying rollers 1713 convey the recording medium 1714. The recording medium 1714 is, for example, paper. The fixing device 1715 fixes the image formed on the recording medium 1714.

FIGS. 16B and 16C are schematic views illustrating the exposure light source 1708 and how a plurality of light-emitting portions 1726 is arranged on a long substrate. An arrow 1727 indicates a direction that is parallel to a shaft of the photosensitive member 1707 and is a column direction in which the organic light-emitting apparatus is arranged. This column direction corresponds to the direction of the shaft around which the photosensitive member 1707 rotates. This direction can also be referred to as a long axis direction of the photosensitive member 1707. FIG. 16B illustrates an arrangement in which the light-emitting portions 1726 are arranged along the long axis direction of the photosensitive member 1707. The light-emitting portion 1726 includes the organic light-emitting apparatus disclosed herein. FIG. 16C illustrates an arrangement that is different from the arrangement illustrated in FIG. 16B and in which the light-emitting portions 1726 are alternately arranged in the column direction in both the first column and the second column. The first column and the second column are arranged at different locations in the row direction. In the first column, the plurality of light-emitting portions 1726 is arranged with spaces in between. In the second column, the light-emitting portions 1726 are placed at positions corresponding to the spaces between the light-emitting portions 1726 in the first column. In other words, the plurality of light-emitting portions 1726 is also arranged with spaces in between in the row direction. The arrangement illustrated in FIG. 16C can also be referred to as, for example, an arrangement in a lattice pattern, a staggered grid pattern, or a checkerboard pattern.

As described above, by using the organic light-emitting apparatus disclosed herein, stable display with suitable image quality can be achieved even during long-term display.

Further, since the drive circuit and the transparent electrode layer, or the drive circuit and the reflective layer, are electrically connected via the conductive plug, the step height is reduced compared to conventional configurations, making it possible to realize an organic light-emitting apparatus with reduced local thinning of the light-emitting layer and reduced breakage of the semi-transparent electrode due to the step height.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-093039, filed Jun. 7, 2024, which is hereby incorporated by reference herein in its entirety.

What is claimed is:

1. An organic light-emitting apparatus comprising:
a pixel including a first sub-pixel and a second sub-pixel;
a drive circuit disposed on one main surface of a substrate;
a first insulating layer covering the drive circuit;
reflective layers and first electrodes disposed on the first insulating layer, one of the reflective layers and one of the first electrodes being disposed for the first sub-pixel and another of the reflective layers and another of the first electrodes being disposed for the second sub-pixel;
a second insulating layer disposed on the first insulating layer, the second insulating layer separating the first electrode of the first sub-pixel from the first electrode of the second sub-pixel;
an organic compound layer disposed on the first electrode and the second insulating layer, the organic compound layer including a light-emitting layer; and
a second electrode on the organic compound layer,
wherein in the first sub-pixel, the drive circuit and the first electrode are electrically connected to each other via a conductive plug provided in the first insulating layer and including a material different from a material of the first electrode,
wherein in the first sub-pixel, the first electrode is in contact with the first insulating layer, the conductive plug, and the reflective layer, and
wherein the first electrode of the first sub-pixel is different in thickness from the first electrode of the second sub-pixel.

2. The organic light-emitting apparatus according to claim 1, wherein the pixel includes a third sub-pixel, and in the third sub-pixel, the drive circuit and a first electrode of the first electrodes are electrically connected to each other via the conductive plug provided in the first insulating layer and including a material different from a material of the first electrode.

3. The organic light-emitting apparatus according to claim 1, wherein the pixel includes a third sub-pixel, and in the third sub-pixel, the drive circuit and a reflective layer of the reflective layers are electrically connected to each other via the conductive plug.

4. The organic light-emitting apparatus according to claim 1, wherein, in the first sub-pixel, the first electrode covers each side of the reflective layer around an entire perimeter of the reflective layer.

5. The organic light-emitting apparatus according to claim 1, wherein, in the first sub-pixel, the first electrode in contact with the conductive plug is also in contact with a side of the conductive plug.

6. The organic light-emitting apparatus according to claim 1, wherein the conductive plug is formed of metal.

7. A display apparatus comprising:
a display unit including the organic light-emitting apparatus according to claim 1; and
a housing in which the display unit is provided.

8. A photoelectric conversion apparatus comprising:
an image sensor configured to receive light; and
a display unit configured to display an image captured by the image sensor,
wherein the display unit includes the organic light-emitting apparatus according to claim 1.

9. An electronic device comprising:
a display unit including the organic light-emitting apparatus according to claim 1;
a housing in which the display unit is provided; and
a communication unit disposed in the housing and configured to communicate externally.

10. A wearable device comprising:
a display unit including the organic light-emitting apparatus according to claim 1;
an optical system configured to concentrate light from the display unit; and
a control apparatus configured to control a display operation of the display unit.

11. An illumination apparatus comprising:
a light source including the organic light-emitting apparatus according to claim 1; and
a housing in which the light source is provided.

12. A movable unit comprising:
a lighting fixture including the organic light-emitting apparatus according to claim 1; and
a body in which the lighting fixture is provided.

13. An image forming apparatus comprising:
a photosensitive member; and
an exposure light source configured to expose the photosensitive member,
wherein the exposure light source includes the organic light-emitting apparatus according to claim 1.
